(19) United States
(12) Patent Application Publication
(10) Pub. No.: US 2022/0352481 A1
(43) Pub. Date: Nov. 3, 2022

(54) LIGHT-EMITTING DEVICE

(71) Applicant: SHARP KABUSHIKI KAISHA, Sakai City, Osaka (JP)

(72) Inventors: TAZUKO KITAZAWA, Sakai City, Osaka (JP); YOSHIHIRO UETA, Sakai City, Osaka (JP)

(73) Assignees: SHARP KABUSHIKI KAISHA, Sakai City, Osaka (JP); SHARP KABUSHIKI KAISHA, Sakai City, Osaka (JP)

(21) Appl. No.: 17/763,293

(22) PCT Filed: Oct. 8, 2019
(86) PCT No.: PCT/JP2019/039581

§ 371 Date: Mar. 24, 2022

(51) Int. Cl. H01L 51/50; H01L 27/32; H01L 51/52

(52) U.S. Cl. CPC H01L 51/502; H01L 27/3218; H01L 51/5218; H01L 51/5234

(57) ABSTRACT

A light-emitting device of a transmissive type includes, as subpixels, a red subpixel including a red light-emitting layer, a green subpixel including a green light-emitting layer, and a blue subpixel including a blue light-emitting layer arranged in parallel with one another. The display light-emitting device includes an opaque region that overlaps at least the red subpixel and the green subpixel, each in its entirety, in a plan view and blocks background light, and a transparent region that overlaps at least a portion of the blue subpixel in a plan view and transmits background light.

### TECHNICAL FIELD

The present invention relates to a light-emitting device.

### BACKGROUND ART

PTL 1 discloses a transparent light-emitting device including a region that transmits background light, separate from a light-emitting region. PTL 2 discloses a transparent light-emitting device in which all electrodes in the light-emitting region are formed as transparent electrodes, thereby causing the light-emitting region to transmit background light.

### CITATION LIST

### Patent Literature

PTL JP 2018-006263 A
PTL 2: JP 2018-189937 A

### SUMMARY OF INVENTION

### Technical Problem

In a transmissive-type light-emitting device such as described in PTL 1, because it is necessary to separately secure a transparent region that transmits background light, a ratio of the light-emitting region to the entire light-emitting face of the light-emitting device is decreased. Further, in a transmissive-type light-emitting device such as described in PTL 2, a red light-emitting layer and a green light-emitting layer may unexpectedly emit light by being excited by the background light, causing the white balance to be off.

### Solution to Problem

In order to solve the problems described above, a light-emitting device according to an aspect of the present invention is a light-emitting device of a transmissive type provided with, as subpixels, a red subpixel including a red light-emitting layer, a green subpixel including a green light-emitting layer, and a blue subpixel including a blue light-emitting layer arranged in parallel with one another. The light-emitting device includes an opaque region that overlaps at least the red subpixel and the green subpixel, each in its entirety, in a plan view and blocks background light, and a transparent region that overlaps at least a portion of the blue subpixel in a plan view and transmits background light.

### Advantageous Effects of Invention

According to an aspect of the present invention, it is possible to provide a light-emitting device of a transmissive type that suppresses a change in a white balance of a light-emitting face due to background light while suppressing a decrease in a ratio of a light-emitting region to the entire light-emitting face.

### BRIEF DESCRIPTION OF DRAWINGS

FIG. 1 is a schematic top view of a display device according to a first embodiment of the present invention.

FIG. 2 is a schematic cross-sectional view of the display device according to the first embodiment of the present invention.

FIG. 3 is a schematic view for explaining an area ratio of a transparent region and an opaque region and an area ratio of each light-emitting subpixel of the display device according to the first embodiment of the present invention.

FIG. 4 is a schematic top view of a display device according to a comparative embodiment of the present invention.

FIG. 5 is a schematic cross-sectional view of the display device according to the comparative embodiment of the present invention.

FIG. 6 is a schematic view for explaining an area ratio of a transparent region and an opaque region and an area ratio of each light-emitting subpixel and a non-light-emitting transparent region of the display device according to the comparative embodiment of the present invention.

FIG. 7 is a schematic view for explaining an area ratio of a transparent region and an opaque region and an area ratio of each light-emitting subpixel of the display device according to a modified example of the present invention.

FIG. 8 is a schematic top view of the display device according to a second embodiment of the present invention.

FIG. 9 is a schematic cross-sectional view of the display device according to the second embodiment of the present invention.

FIG. 10 is a schematic view for explaining an area ratio of a transparent region and an opaque region and an area ratio of each light-emitting subpixel and a non-light-emitting transparent region of the display device according to the second embodiment of the present invention.

FIG. 11 is a schematic top view of the display device according to a third embodiment of the present invention,

FIG. 12 is a schematic cross-sectional view of the display device according to the third embodiment of the present invention.

FIG. 13 is a schematic view for explaining an area ratio of a transparent region and an opaque region and an area ratio of each light-emitting subpixel of the display device according to the third embodiment of the present invention.

FIG. 14 is a schematic top view of the display device according to a fourth embodiment of the present invention.

FIG. 15 is a schematic cross-sectional view of the display device according to the fourth embodiment of the present invention.

FIG. 16 is a schematic view for explaining an area ratio of a transparent region and an opaque region and an area ratio of each light-emitting subpixel and a non-light-emitting transparent region of the display device according to the fourth embodiment of the present invention.

FIG. 17 is a schematic view for explaining an area ratio of a transparent region and an opaque region and an area ratio of each light-emitting subpixel of a display device according to a fifth embodiment of the present invention.

### DESCRIPTION OF EMBODIMENTS

### First Embodiment

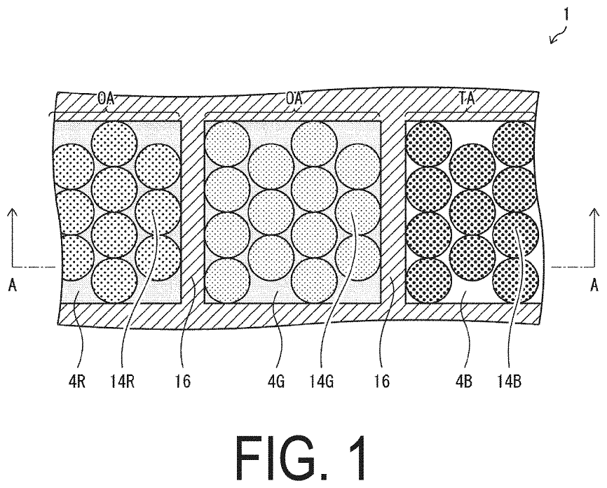

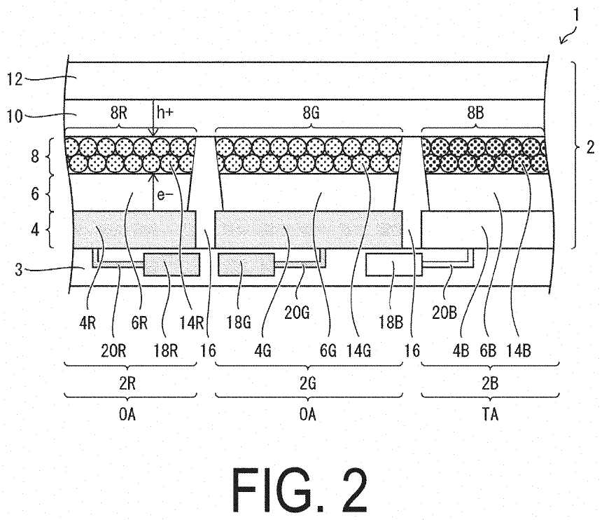

FIG. 1 is a top enlarged view of a display device 1 according to the present embodiment. FIG. 2 is a schematic cross-sectional view of the display device 1 according to the present embodiment, and is a cross-sectional view taken along line A-A in FIG. 1. Note that, in FIG. 1, for ease of illustration of a transparent region TA and an opaque region OA described below, a cathode electrode 4, a light-emitting layer 8, and an edge cover 16 are selectively illustrated.

As illustrated in FIG. 2, the display device 1 according to the present embodiment includes a light-emitting element 2 and an array substrate 3. The display device 1 has a structure in which each layer of the light-emitting element 2 is layered on the array substrate 3 in which a transistor described below is formed for each light-emitting subpixel. Note that, in the present specification, a direction from the light-emitting element 2 to the array substrate 3 of the display device 1 is referred to as “downward,” and a direction from the array substrate 3 to the light-emitting element 2 of the display device 1 is referred to as “upward”.

The light-emitting element 2 includes an electron transport layer 6, the light-emitting layer 8, a hole transport layer 10, and an anode electrode 12 on the cathode electrode 4 in order from a lower layer. The cathode electrode 4 of the light-emitting element 2 formed in an upper layer above the array substrate 3 is electrically connected to thin-film transistors (TFTs) of the array substrate 3.

Here, each of the cathode electrode 4, the electron transport layer 6, and the light emitting layer 8 is separated by the edge cover 16. Particularly, in the present embodiment, the cathode electrode 4 is separated into a cathode electrode 4R of a red subpixel, a cathode electrode 4G of a green subpixel, and a cathode electrode 4B of a blue subpixel by the edge cover 16. Further, the electron transport layer 6 is separated into an electron transport layer 6R of the red subpixel, an electron transport layer 6G of the green subpixel, and an electron transport layer 6B of the blue subpixel by the edge cover 16. Furthermore, the light-emitting layer 8 is separated into a red light-emitting layer 8R, a green light-emitting layer 8G, and a blue light-emitting layer 8B by the edge cover 16. Note that the hole transport layer 10 and the anode electrode 12 are not separated by the edge cover 16 and are commonly formed. As illustrated in FIG. 2, the edge cover 16 may be formed in a position covering a side surface and an area at or near a peripheral end portion of an upper face of the cathode electrode 4.

Further, in the light-emitting element 2 according to the present embodiment, a red subpixel 2R is formed of the cathode electrode 4R, the electron transport layer 6R, and the red light-emitting layer 8R that have an island shape, and the hole transport layer 10 and the anode electrode 12 that are common. Similarly, a green subpixel 2G is formed of the cathode electrode 4G, the electron transport layer 6G, and the green light-emitting layer 8G that have an island shape, and the hole transport layer 10 and the anode electrode 12 that are common. Similarly, a blue subpixel 2B is formed of the cathode electrode 4B, the electron transport layer 6B, and the blue light-emitting layer 8B that have an island shape, and the hole transport layer 10 and the anode electrode 12 that are common. That is, the display device 1 according to the present embodiment includes the red subpixel 2R, the green subpixel 2G, and the blue subpixel 2B as light-emitting subpixels.

In the present embodiment, the red light-emitting layer 8R included in the red subpixel 2R emits red light, the green light-emitting layer 8G included in the green subpixel 2G emits green light, and the blue light-emitting layer 8B included in the blue subpixel 2B emits blue light. That is, the light-emitting element 2 includes a plurality of light-emitting subpixels in parallel with one another for each light emission wavelength of the light-emitting layer 8, and includes the cathode electrode 4, the electron transport layer 6, and the light-emitting layer 8 for each light-emitting subpixel. Note that the light-emitting element 2 includes the hole transport layer 10 and the anode electrode 12 common to all of the light-emitting subpixels.

Here, the blue light is light having the central wavelength of the light emission in a wavelength band from 400 nm to 500 nm. The green light is light having the central wavelength of the light emission in a wavelength band longer than 500 nm and shorter than or equal to 600 nm. The red light is light having the central wavelength of the light emission in a wavelength band longer than 600 nm and shorter than or equal to 780 nm.

In the light-emitting element 2 according to the present embodiment, one group including one red subpixel 2R, one green subpixel 2G, and one blue subpixel 2B may be one pixel in the light-emitting element 2. Further, in FIG. 1 and FIG. 2, only one pixel is illustrated, but in the present embodiment, the light-emitting element 2 may additionally include a plurality of pixels.

In the present embodiment, description is given using the display device 1 in which the light-emitting element 2 includes a plurality of pixels as an example of the light-emitting device. Nevertheless, the light-emitting device according to the present embodiment is not limited thereto, and the light-emitting element 2 may be a light-emitting device including only one red subpixel 2R, one green subpixel 2G, and one blue subpixel 2B.

The cathode electrode 4 and the anode electrode 12 include conductive materials and are electrically connected to the electron transport layer 6 and the hole transport layer 10, respectively. In the present embodiment, the cathode electrode 4R and the cathode electrode 4G are reflective electrodes, and the cathode electrode 4B is a transparent electrode. Further, the anode electrode 12 is a transparent electrode. The cathode electrode 4R and the cathode electrode 4G may include, for example, a metal material. In. the present embodiment, the cathode electrode 4 includes a metal material. The metal material is preferably Al, Cu, Au, Ag, or the like having a high reflectivity of visible light. For the cathode electrode 4B and the anode electrode 12, ITO, IZO, AZO, or GZO, for example, may be used, and may be formed as a film using a sputtering method or the like.

The light-emitting layer 8 is a layer that emits light due to the occurrence of recombination between electrons injected from the cathode electrode 4 and transported via the electron transport layer 6, and positive holes injected from the anode electrode 12 and transported via the hole transport layer 10. In the present embodiment, quantum dots (semiconductor nanoparticles) layered in one to a few layers are provided in each light-emitting subpixel as the light-emitting material. As illustrated in FIG. 1 and FIG. 2, the light-emitting layer 8 includes a red quantum dot 14R (first quantum dot) in the red light-emitting layer 8R, a green quantum dot 14G (second quantum dot) in the green light-emitting layer 8G, and a blue quantum dot 14B in the blue light-emitting layer 8B. That is, the light-emitting layer 8 includes quantum dots of a plurality of types, and includes quantum dots of the same type in the same light-emitting subpixel.

The light-emitting layer 8 can be formed into a film by separately patterning for each light-emitting subpixel from a dispersion liquid in which quantum dots are dispersed in a solvent such as hexane or toluene using a spin coating method, an ink-jet method, or the like. The dispersion liquid may be mixed with a dispersion material such as thiol or amine. In addition, the light-emitting layer 8 can be formed by adopting a technique of forming a light-emitting layer including known quantum dots, such as a photolithography method or an electrodeposition method.

The quantum dots 14R, 14G, 1.4B are each a light-emitting material that has a valence band level (equal to an ionization potential) and a conduction band level (equal to an electron affinity), and emits light through recombination of positive holes in the valence band level with electrons in the conduction band level. Because light emitted from the quantum dots 14R, 14G, 14B has a narrower spectrum due to a quantum confinement effect, it is possible to obtain the emitted light with relatively deep chromaticity.

The quantum dots 14R, 14G, 14B may include one or a plurality of semiconductor materials selected from a group including, for example, Cd, S, Te, Se, Zn, In, N, P, As, Sb, Al, Ga, Pb, Si, Ge, Mg, and compounds thereof. Further, the quantum dots 14R, 14G, 14B may be a two-component core type, a three-component core type, a four-component core type, a core-shell type, or a core multi-shell type.

The electron transport layer 6 is a layer that transports electrons from the cathode electrode 4 to the light-emitting layer 8. The electron transport layer 6 may have a function of inhibiting transport of positive holes. The electron transport layer 6 includes materials different from each other in each of the electron transport layer 6R, the electron transport layer 6G, and the electron transport layer 6B. The electron transport layer 6 may include, for example, ZnO, MgZnO, TiO₂, Ta₂O₃, or SrTiO₃, or may include a plurality of materials among them for each light-emitting subpixel. The electron transport layer 6 may be formed into a film for each light-emitting subpixel by a sputtering method, and may include a material common to all light-emitting subpixels.

The hole transport layer 10 is a layer that transports positive holes from the anode electrode 12 to the light-emitting layer 8, The hole transport layer 10 may have a function. of inhibiting transport of electrons. The hole transport layer 10 may include, for example, PEDOT: PSS, TFB, or poly-TPD, or may include a plurality of materials among them.

In the present embodiment, the electron transport layer 6, the light-emitting layer 8, and the hole transport layer 10 include a transparent material. Accordingly, the light-emitting element 2 can remove light emitted from the light-emitting layer 8 from the anode electrode 12 side, which is a transparent electrode. Accordingly, the display device 1 includes a display surface on the anode electrode 12 side.

However, the electrodes formed in the blue subpixel 2B, that is, the cathode electrode 4B and the anode electrode 12, are both transparent electrodes. Therefore, light from a back face side of the display device 1, that is, light commonly referred to as background light, is transmitted through the blue subpixel 2B.

Accordingly, the display device 1 is configured as a transmissive-type display device including the opaque region OA in a position including the red subpixel 2R and the green subpixel 2G, and including the transparent region TA in a position including the blue subpixel 2B. That is, a viewer of the display surface of the display device 1 can observe the background of the display device 1 through the transparent region TA.

In the present embodiment, members not included in a subpixel, such as the edge cover 16, are not included in the opaque region OA and the transparent region TA. Note that the member may be a transparent member or an opaque member.

Incidentally, the array substrate 3 includes a subpixel circuit including a transistor such as a thin film transistor (TFT) for each of the light-emitting subpixels described. above. In particular, the array substrate 3 includes a subpixel circuit 18R for the red subpixel 2R, a subpixel circuit 18G for the green subpixel 2G, and a subpixel circuit 18B for the blue subpixel 2B. The subpixel circuit 18R is electrically connected to the cathode electrode 4R via a lead wiring line 20R, Similarly, the subpixel circuit 18G is electrically connected to the cathode electrode 4G via a lead wiring line 20G. Furthermore, the subpixel circuit 18B is electrically connected to the cathode electrode 4B via a lead wiring line 20B.

In the present embodiment, the lead wiring line 20B is formed in a position overlapping the cathode electrode 4B. That is, the lead wiring line 20B is formed in a position overlapping the transparent region TA. Therefore, similarly to the cathode electrode 4B and the anode electrode 12, the lead wiring line 20B is preferably constituted by a transparent member. Because the lead wiring line 20B is a transparent member, the lead wiring line 20B does not inhibit the transmission of background light in the transparent region TA.

In contrast, the subpixel circuit 18R and the lead wiring line 20R are formed in positions overlapping the cathode electrode 4R. Similarly, the subpixel circuit 18G and the lead wiring line 20G are formed in positions overlapping the cathode electrode 4G. Further, the subpixel circuit 18B is formed in a position overlapping a light-emitting subpixel of another color or the edge cover 16 that is opaque, adjacent to the blue subpixel 2B.

That is, the subpixel circuits 18R, 18G, 18B and the lead wiring lines 20R, 20G are formed in positions overlapping the opaque region OA. Therefore, the subpixel circuits 18R, 18G, 18B, and the lead wiring lines 20R, 20G do not inhibit transmission of background light in the transparent region TA even if constituted by an opaque material including a metal material or the like.

Each of the subpixel circuits includes a capacitor that holds data voltage and includes, as transistors, a drive transistor that controls the current of the light-emitting element, a writing transistor that writes the data voltage to the capacitor, and the like. Because each subpixel circuit is provided in a position overlapping the opaque region as described above, these transistors are also formed in positions overlapping the opaque region, Therefore, in the present embodiment, the light from the light-emitting layer 8 or the background light or the like irradiated onto the transistors provided in each subpixel circuit can be reduced, making it possible to reduce deterioration of the transistors.

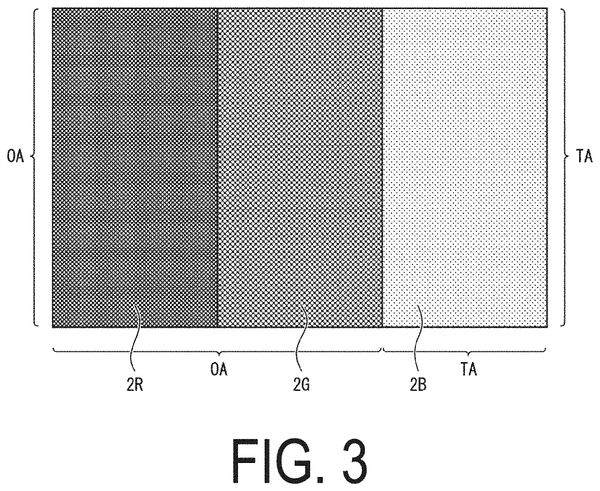

The relationship between an area ratio of the transparent region TA and the opaque region OA of the display device 1 and an area ratio of each light-emitting layer in the present embodiment will now be described with reference to FIG. 3. FIG. 3 is a schematic view illustrating the ratio of the area of each light-emitting subpixel to the total area of the red subpixel 2R, the green subpixel 2G, and the blue subpixel 2B in the present embodiment.

Note that, the schematic views illustrating the ratio of the area of each member in the display device according to each embodiment selectively illustrate, of the total area of the display device 1 according to the present embodiment, only the areas of the opaque region OA and the transparent region TA for the sake of simplicity. That is, in FIG. 3, illustration of the ratio of the area of the display device 1 in positions overlapping the edge cover 16 is omitted, for example. Further, the schematic views illustrating the ratio of the area of each member in the display device according to each embodiment illustrate the area of each display device in a plan view.

The total area of the opaque region OA and the transparent region TA is denoted as S. Further, a ratio of the area of the blue subpixel 2B to the total area of the red subpixel 2R, the green subpixel 2G, and the blue subpixel 2B is denoted as a. Note that a is a real number greater than 0 and less than 1. Hereinafter, unless otherwise indicated, S and a are based on the definitions described above.

In this case, the area of the blue subpixel 2B can be expressed as aS. Further, in a case in which the areas of the red subpixel 2R and the green subpixel 2G are equal to each other, the areas of the red subpixel 2R and the green subpixel 2G can be respectively expressed as (S−aS)/2=(1−a)S/2.

Here, in the present embodiment, the blue subpixel 2B constitutes the transparent region TA, and the red subpixel 2R and the green subpixel 2G constitute the opaque region OA. Therefore, the area of the transparent region TA is aS, and the area of the opaque region OA is (1−a)S.

In the present embodiment, for example, the areas of the light-emitting subpixels may be equal to each other. In this case, since a=1/3, the area of each light-emitting subpixel is S/3. Further, the area of the transparent region TA is S/3, and the area of the opaque region OA is 2S/3.

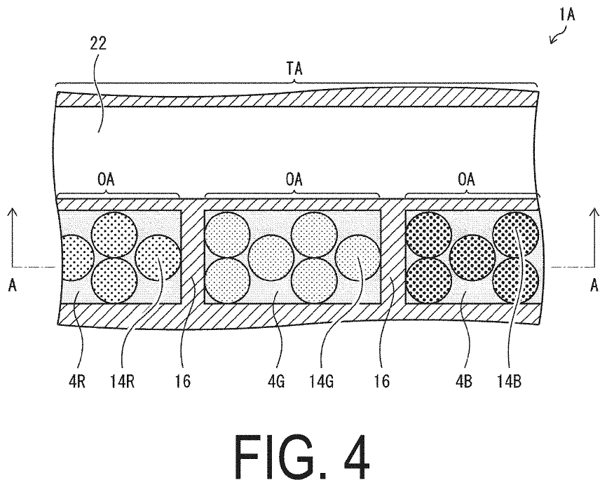

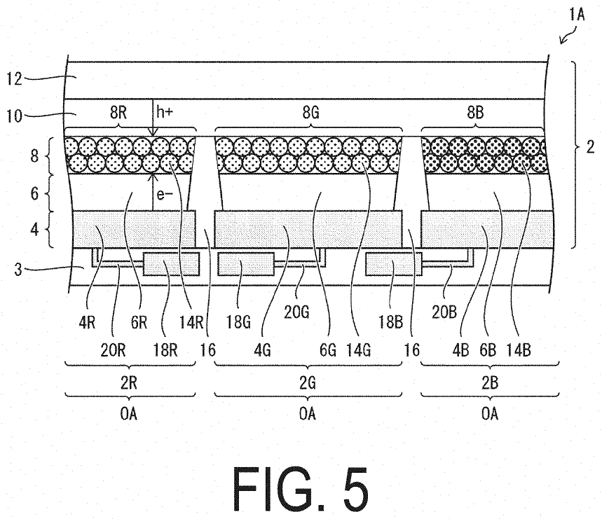

Next, a display device according to a comparative embodiment will be described. FIG. 4 is a top enlarged view of a display device 1A according to the comparative embodiment. FIG. 5 is a schematic cross-sectional view of the display device 1A according to the comparative embodiment, and is a cross-sectional view taken along line A-A in FIG. 4.

The display device 1A according to the comparative embodiment has a configuration different from that of the display device 1 according to the present embodiment in further including, in addition to the red subpixel 2R, the green subpixel 2G, and the blue subpixel 2B, a non-light-emitting transparent region 22. The non-light-emitting transparent region 22 surrounds the red subpixel 2R, the green subpixel 2G, and the blue subpixel 2B.

For example, only the transparent array substrate 3 may be formed in the non-light-emitting transparent region 22. Furthermore, the subpixel circuits and the lead wiring lines need not be formed in the non-light-emitting transparent region 22. That is, a void may be formed on the array substrate 3 in the non-light-emitting transparent region 22. Further, a transparent resin, for example, may be formed on the array substrate 3 in the non-light-emitting transparent region 22. Therefore, in the non-light-emitting transparent region 22, background light is transmitted, and light from the display device, including light emitted from the light-emitting layer 8, cannot be obtained from the non-light-emitting transparent region 22.

Note that, in the present specification, the non-light-emitting transparent region 22 is treated as a non-light-emitting transparent subpixel that does not emit light. That is, in the present specification, the transparent region TA includes the non-light-emitting transparent region 22.

Furthermore, the display device 1A according to the comparative embodiment also differs in configuration from the display device 1 according to the present embodiment in that the cathode electrode 4B of the blue subpixel 2B is a reflective electrode, and the subpixel circuit 18B and the lead wiring line 20B are formed in positions overlapping the cathode electrode 4B. Accordingly, the lead wiring line 20B is constituted by an opaque material.

Therefore, the non-light-emitting transparent region 22 transmits the background light of the display device 1A according to the comparative embodiment, and does not emit light by itself. Further, the display device 1A according to the comparative embodiment transmits the background light only in the non-light-emitting transparent region 22, and blocks the background light in all light-emitting subpixels. That is, in the comparative embodiment, the opaque region OA includes the red subpixel 2R, the green subpixel 2G, and the blue subpixel 2B, and the transparent region TA includes the non-light-emitting transparent region 22.

Except for the point described above, the display device 1A according to the comparative embodiment may have the same configuration as that of the display device 1 according to the present embodiment. For example, the layered structure of each light-emitting subpixel of the display device 1A according to the comparative embodiment has the same configuration as the layered structure of each light-emitting subpixel of the display device 1 according to the present embodiment.

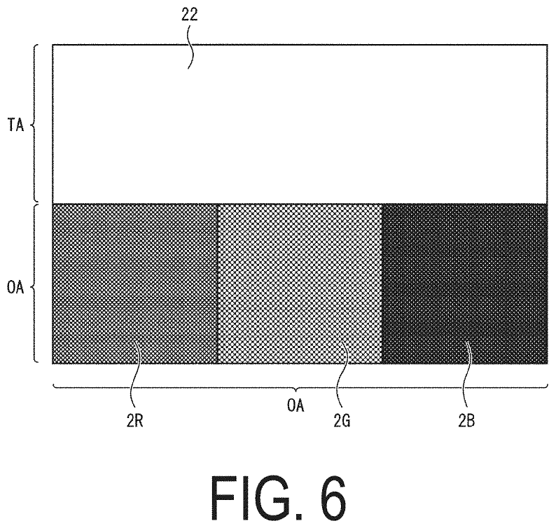

FIG. 6 is a schematic view illustrating the ratio of the area of each light-emitting subpixel and the ratio of the area of the non-light-emitting transparent region to the total area of the red subpixel 2R, the green subpixel 2G, the blue subpixel 2B, and the non-light-emitting transparent region 22 in the comparative embodiment.

In the comparative embodiment as well, the total area of the opaque region OA and the transparent region TA is denoted as S. In the comparative embodiment, the ratio of the non-light-emitting transparent region 22 to the total area of the red subpixel 2R, the green subpixel 2G, the blue subpixel 2B, and the non-light-emitting transparent region 22 is 1/2. Therefore, in the comparative embodiment, the area of the non-light-emitting transparent region 22 is expressed as S/2.

Further, in the present embodiment, the areas of the red subpixel 2R, the green subpixel 2G, and the blue subpixel 2B are equal to each other. Therefore, in the comparative embodiment, the areas of the light-emitting subpixels are all S/6.

Here, in the comparative embodiment, the non-light-emitting transparent region 22 constitutes the transparent region TA, and the red subpixel 2R, the green subpixel 2G, and the blue subpixel 2B constitute the opaque region OA. Therefore, the area of the transparent region TA and the area of the opaque region OA are both S/2.

The area of each light-emitting subpixel in the present embodiment is twice the area of each light-emitting subpixel in the comparative embodiment. That is, in a case in which the luminance obtained from the light-emitting subpixel is equal per unit surface area, the luminance of each light-emitting subpixel in the present embodiment is twice the luminance of each light-emitting subpixel in the comparative embodiment. Further, the display device 1 according to the present embodiment can secure the transparent region TA of S/3, and constitutes a transmissive-type display device.

Further, in the display device 1 according to the present embodiment, the red subpixel 2R and the green subpixel 2G are formed in the opaque region OA. Therefore, optical excitation between the red quantum dot 14R of the red subpixel 2R and the green quantum dot 14G of the green subpixel 2G due to background light is reduced.

Accordingly, the display device 1 according to the present embodiment suppresses unexpected light emission of the red subpixel 2R and the green subpixel 2G due to background light, and improves the white balance.

Thus, the display device 1 according to the present embodiment can provide a transmissive-type display device that suppresses a decrease in luminance of each light-emitting subpixel while suppressing a change in white balance. In particular, in the present embodiment, the red subpixel 2R and the green subpixel 2G include quantum dots that are readily optically excited as light-emitting materials. Therefore, the display device 1 according to the present embodiment has a more marked effect of suppressing a change in white balance.

In the present embodiment, the blue subpixel 2B overlaps the transparent region TA in its entirety. Therefore, the display device 1 according to the present embodiment can more efficiently secure the area of the transparent region TA.

Here, in the comparative embodiment, the ratio b of the non-light-emitting transparent region 22 to the total area S is 1/2. That is, half of the total area S is the non-light-emitting transparent region 22. In this case, the area of each light-emitting subpixel is S/6. Further, the area of the transparent region TA and the area of the opaque region OA are both S/2.

In the present embodiment, in a case in which the areas of each light-emitting subpixel are equal to each other, the area of each light-emitting subpixel is S/3, as described above. Therefore, the areas of each light-emitting subpixel in the present embodiment are all greater than S/6, which is the area of each light-emitting subpixel in the comparative embodiment. Accordingly, the display device 1 according to the present embodiment can more efficiently secure the luminance of each light-emitting subpixel in comparison to the display device 1A according to the comparative embodiment.

Note that, in the present embodiment, in the light-emitting subpixel in which the reflective electrode is formed, the light emitted from the light-emitting layer to the reflective electrode can also be removed on the display surface side. Therefore, in the case of the same area, in the light-emitting subpixel, the luminance at the position overlapping the opaque region OA is understood to be ideally twice the luminance at the position overlapping the transparent region TA.

Therefore, in order for the luminance of the blue subpixel 2B according to the present embodiment to be greater than or equal to the luminance of the blue subpixel 2B according to the comparative embodiment, the area of the blue subpixel 2B according to the present embodiment needs to be a magnification of the area of the blue subpixel 2B according to the comparative embodiment. Therefore, in order for the luminance of the blue subpixel 2B according to the present embodiment to be greater than or equal to the luminance of the blue subpixel 2B according to the comparative embodiment, the area of the blue subpixel 2B according to the present embodiment need only be S/3 or greater.

As described above, in the present embodiment, the areas of the red subpixel 2R and the green subpixel 2G are equal to each other. Here, ideally, a reflectivity 1Z of light of the reflective electrode formed in a position overlapping the opaque region OA is 1, and a reflectivity R′ of light in the transparent electrode formed in a position overlapping the transparent region TA is assumed to be 0. In this case, in order for the luminance of each light-emitting subpixel in the present embodiment to be greater than or equal to the luminance of each light-emitting subpixel in the comparative embodiment, the following relationship (1) need only be satisfied.

[Relationship1]

13≥a≥23 (1)

However, in reality, in a case in which the areas of the opaque region OA and the transparent region TA are the same in the light-emitting subpixel, the luminance at the position overlapping the opaque region OA is twice the luminance at the position overlapping the transparent region TA or less. This is actually because the reflectivity R of light of the reflective electrode formed in a position overlapping the opaque region OA is less than 1, and the reflectivity R′ of light in the transparent electrode formed in a position overlapping the transparent region TA is greater than 0. Thus, in order for the luminance of the blue subpixel 2B according to the present embodiment to be greater than or equal to the luminance of the blue subpixel 2B according to the comparative embodiment, the area of the blue subpixel 2B according to the present embodiment need only be (1+R)S/6(1R′) or greater.

Accordingly, when the actual reflectivity of the reflective electrode and transparent electrode is considered, in order for the luminance of each light-emitting subpixel in the present embodiment to be greater than or equal to the luminance of each light-emitting subpixel in the comparative embodiment, the following relationship (2) need only be satisfied.

$$\begin{matrix}[ Relationship 2 ] & \\ \frac{1 + R}{6 ( 1 + {R}^{′} )} \leq a \leq \frac{2}{3} & ( 2 )\end{matrix}$$

### Modified Example 1

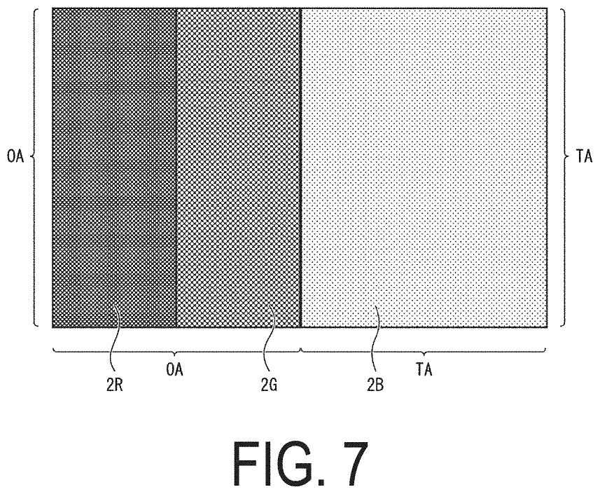

The display device 1 according to a modified example of the present embodiment will now be described with reference to FIG. 7. The display device 1 according to the present modified example may have the same configuration as that of the display device 1 according to the present embodiment except the ratio of the area of the blue subpixel 2B to the total area of the red subpixel 2R, the green subpixel 2G, and the blue subpixel 2B.

FIG. 7 is a schematic view illustrating the ratio of the area of each light-emitting subpixel to the total area of the red subpixel 2R, the green subpixel 2G, and the blue subpixel 2B in the present modified example.

In the present modified example, a=1/2. That is, in the present modified example, half of the total area of the red subpixel 2R, the green subpixel 2G, and the blue subpixel 2B is equal to the area of the blue subpixel 2B. Accordingly, the area of blue subpixel 2B is S/2.

In the present modified example as well, when the areas of the red subpixel 2R and the green subpixel 2G are equal to each other, the areas of the red subpixel 2R and the green subpixel 2G are both S/4. Further, the area of the transparent region TA and the area of the opaque region OA are both S/2.

Accordingly, the areas of each light-emitting subpixel in the present modified example are all greater than S/6, which is the area of each light-emitting subpixel in the comparative embodiment. In addition, as the area of the transparent region TA, S/2, which is the same as the area of the transparent region TA in the comparative embodiment, can be secured. Thus, in the display device 1 according to the present modified example, compared to the display device 1A according to the comparative embodiment, the luminance of each light-emitting subpixel can be more efficiently secured and the area of the transparent region TA equivalent to that of the display device 1A according to the comparative embodiment can be secured.

In the present modified example, the area of the transparent region TA being 1/2 of the total area of the red subpixel 2R, the green subpixel 2G, and the blue subpixel 2B or greater is preferable from the perspective of sufficiently securing the transparency of the display device 1. In other words, it is preferable that the following relationship (3) be satisfied from the perspective of sufficiently securing the transparency of the display device 1.

[Relationship3]

a≥½ (3)

In the present embodiment as well, the areas of the red subpixel 2R and the green subpixel 2G are assumed to be equal to each other. In this case, in order for the luminance of each light-emitting subpixel in the present embodiment to be greater than or equal to the luminance of each light-emitting subpixel in the comparative embodiment and for the area of the transparent region TA to be greater than or equal to S/2, the relationship (2) and the relationship (3) described above need only be satisfied. In other words, it is sufficient that 1/2≤a≤2/3.

Compared to the display device 1A according to the comparative embodiment, the display device 1 according to the present modified example can achieve a 1.5-fold luminance of the blue subpixel 2B and a 1.5-fold luminance of each of the red subpixel 2R and the green subpixel 2G.

In general, in a current injection type light-emitting element, the blue light-emitting element has inferior luminous efficiency compared to those of the red light-emitting element and the green light-emitting element. The display device 1 according to the present modified example is preferable in that the luminance of the blue subpixel 2B can be made higher than the luminance of each of the red subpixel 2R and the green subpixel 2G, making it possible to compensate for low luminous efficiency.

### Second Embodiment

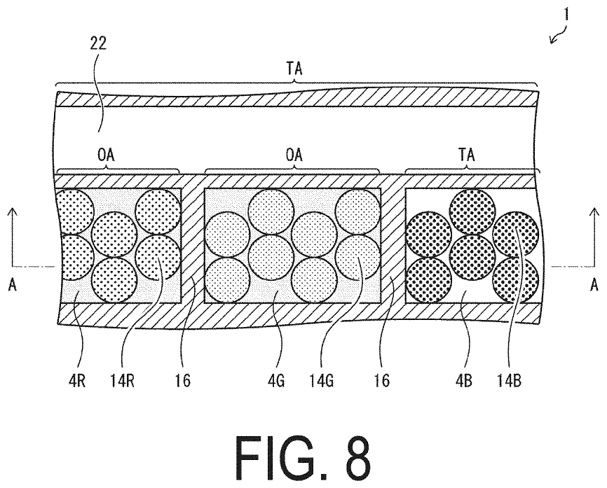

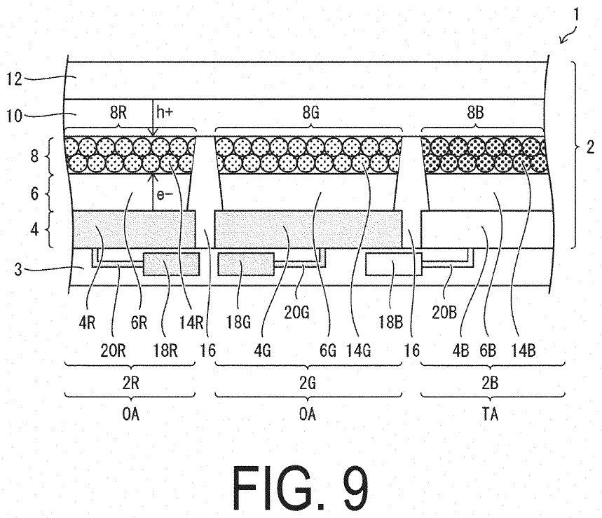

FIG. 8 is a top enlarged view of the display device 1 according to the present embodiment. FIG. 9 is a schematic cross-sectional view of the display device 1 according to the present embodiment, and is a cross-sectional view taken along line A-A in FIG. 8.

The display device 1 according to the present embodiment includes the non-light-emitting transparent region 22 surrounding the red subpixel 2R, the green subpixel 2G, and the blue subpixel 2B. As described in the comparative embodiment, for example, only the transparent array substrate 3 may be formed in the non-light-emitting transparent region 22. That is, a void may be formed on the array substrate 3 in the non-light-emitting transparent region 22. Further, a transparent resin, for example, may be formed on the array substrate 3 in the non-light-emitting transparent region 22. Therefore, the light from the display device, including the light emitted from the light-emitting layer 8, cannot be obtained from the non-light-emitting transparent region 22.

Except for the point described above, the display device 1 according to the present embodiment has the same configuration as that of the display device 1 according to the previous embodiment. That is, in the present embodiment, the opaque region OA includes the red subpixel 2R and the green subpixel 2G, and the transparent region TA includes the blue subpixel 2B and the non-light-emitting transparent region 22.

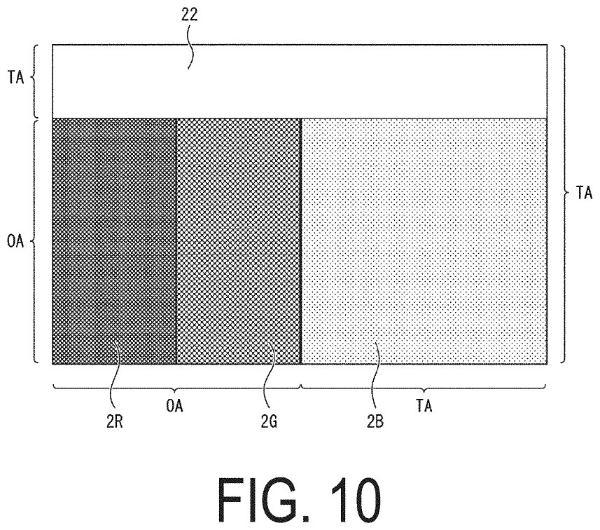

FIG. 10 is a schematic view illustrating the ratio of the area of each light-emitting subpixel and the ratio of the area of the non-light-emitting transparent region to the total area of the red subpixel 2R, the green subpixel 2G, the blue subpixel 2B, and the non-light-emitting transparent region 22 in the present embodiment.

In the present embodiment, the ratio of the non-light-emitting transparent region 22 to the total area of the red subpixel 2R, the green subpixel 2G, the blue subpixel 2B, and the non-light-emitting transparent region 22 is denoted as b. Thus, in the present embodiment, a expresses the ratio of the area of the blue subpixel 2B to the total area of the red subpixel 2R, the green subpixel 2G, and the blue subpixel 2B, excluding the non-light-emitting transparent region 22. Note that b is a real number greater than 0 and less than 1. Hereinafter, b is based on the definition described above.

In this case, the area of the non-light-emitting transparent region 22 can be expressed as bS, and the area of the blue subpixel 2B can be expressed as a(S−bS)=a(1−b)S. Further, in a case in which the areas of the red subpixel 2R and the green subpixel 2G are equal to each other, the areas of the red subpixel 2R and the green subpixel 2G can be respectively expressed as ((1−b)S−a(1−b)S)/2=(1−a)·(1−b)S/2.

Here, in the comparative embodiment, the blue subpixel 2B and the non-light-emitting transparent region 22 constitute the transparent region TA, and the red subpixel 2R and the green subpixel 2G constitute the opaque region OA. Therefore, the area of the transparent region TA is (a+b−ab)S, and the area of the opaque region OA is (1−a)·(1−b).

Accordingly, the luminance of the blue subpixel 2B of the display device 1 according to the present embodiment is 3a(1−b) times the luminance of the blue subpixel 2B of the display device 1A according to the comparative embodiment. Further, the luminance of each of the red subpixel 2R and the green subpixel 2G of the display device 1 according to the present embodiment is 3(1−a)·(1−b) times the luminance of each of the red subpixel 2R and the green subpixel 2G of the display device 1A according to the comparative embodiment. Furthermore, the area of the transparent region TA of the display device 1 according to the present embodiment is 2(a+b−ab) times the area of the transparent region TA of the display device 1A according to the comparative embodiment.

In a case in which the luminance of each light-emitting subpixel of the display device 1 according to the present embodiment is to be made greater than or equal to the luminance of each light-emitting subpixel of the display device 1A according to the comparative embodiment, 3a(1−b)≥1 and 3(1−a) (1−b)≥1 need only be satisfied.

Accordingly, in a case in which the following relationship (4) is satisfied, the luminance of each light-emitting subpixel of the display device 1 according to the present embodiment can be made greater than or equal to the luminance of each light-emitting subpixel of the display device 1A according to the comparative embodiment.

$$\begin{matrix}[ Relationship 4 ] & \\ \frac{1}{3 ( 1 - b )} \leq a \leq \frac{2 - 3 b}{3 ( 1 - b )} & ( 4 )\end{matrix}$$

Note that, in the calculation described above, the luminance at the position overlapping the opaque region OA of the light-emitting subpixel is ideally two-fold compared to that at the position overlapping the transparent region TA. Nevertheless, in reality, the luminance at a position overlapping the opaque region OA of the light-emitting subpixel is twice the luminance at the position overlapping the transparent region TA or less. This is because, as described above, the reflectivity R of light of the reflective electrode formed in a position overlapping the opaque region OA is less than 1, and the reflectivity R′ of light in the transparent electrode formed in a position overlapping the transparent region TA is greater than 0. When the actual reflectivity is considered, the relationship (4) described above is replaced with the following relationship (5).

$$\begin{matrix}[ Relationship 5 ] & \\ \frac{1 + R}{6 ( 1 + {R}^{′} ) ( 1 - b )} \leq a \leq \frac{2 - 3 b}{3 ( 1 - b )} & ( 5 )\end{matrix}$$

Further, in a case in which the area of the transparent region TA of the display device 1 according to the present embodiment is to be made greater than or equal to the area of the transparent region TA of the display device 1A according to the comparative embodiment, 2(a+b−ab)≥1 need only be satisfied. Accordingly, in a case in which the following relationship (6) is satisfied in addition to the above, the area of the transparent region TA of the display device 1 according to the present embodiment can be made greater than or equal to the area of the transparent region TA of the display device 1A according to the comparative embodiment while the luminance of each light-emitting subpixel of the display device 1 according to the present embodiment is improved.

$$\begin{matrix}[ Relationship 6 ] & \\ \frac{1 - 2 b}{2 ( 1 - b )} \leq a & ( 6 )\end{matrix}$$

In the present embodiment, for example, a is 1/2, b is 1/5, and R=1 and R′=0. In this case, the area of the blue subpixel 2B is 2S/5, and the areas of the red subpixel 2R and the green subpixel 2G are each S/5. Further, the area of the transparent region TA is 3 S/5.

Accordingly, in the display device 1 according to the present embodiment, the luminance of the red subpixel 2R, the green subpixel 2G, and the blue subpixel 2B can each be 1.2-fold compared to those in the display device 1A according to the comparative embodiment. Further, the display device 1 according to the present embodiment can secure a transparent region TA having a 1.2-fold area compared to that in the display device 1A according to the comparative embodiment.

The display device 1 according to the present embodiment is also preferable in that the luminance of the blue subpixel 2B can be made higher than the luminance of each of the red subpixel 2R and the green subpixel 2G, making it possible to compensate for low luminous efficiency.

### Third Embodiment

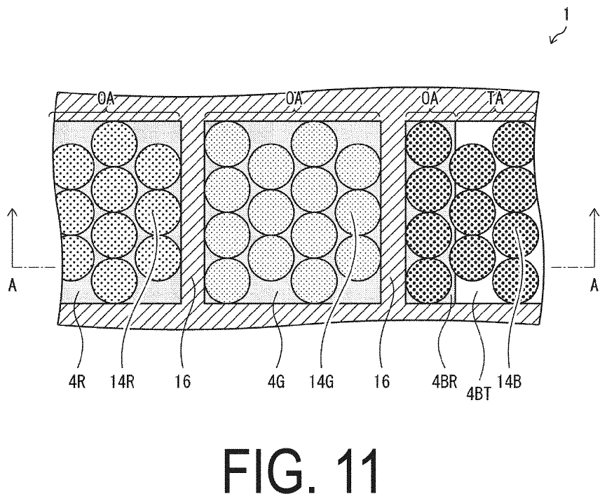

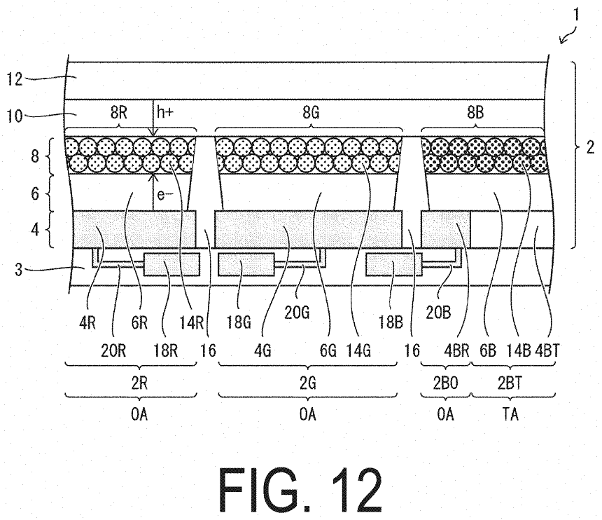

FIG. 11 is a top enlarged view of the display device 1 according to the present embodiment. FIG. 12 is a schematic cross-sectional view of the display device 1 according to the present embodiment, and is a cross-sectional view taken along line A-A in FIG. 11.

In the display device 1 according to the present embodiment, the cathode electrode 4B includes a reflective cathode electrode 4BR, which is a reflective electrode, and a transparent cathode electrode 4BT, which is a transparent electrode. Further, the blue subpixel 2B includes an opaque blue subpixel 2BO in a position overlapping the reflective cathode electrode 4BR, and a transparent blue subpixel 2BT in a position overlapping the transparent cathode electrode 4BT. The reflective cathode electrode 4BR may include the same material as that of the cathode electrode 4R or the cathode electrode 4G. Further, the transparent cathode electrode 4BT may include the same material as that of the anode electrode 12.

In the present embodiment, the transparent blue subpixel 2BT transmits background light similarly to the blue subpixel 2B in each of the embodiments described above. On the other hand, the opaque blue subpixel 2BO blocks background light for the reflective cathode electrode 4BR. Therefore, in the present embodiment, the opaque region OA includes the opaque blue subpixel 2BO in addition to the red subpixel 2R and the green subpixel 2G. Further, in the present embodiment, the transparent region TA includes the transparent blue subpixel 2BT.

That is, in the present embodiment, a portion of the blue subpixel 2B overlaps the opaque region OA. In addition, in a position overlapping the opaque region OA of the blue subpixel 2B, any one of the cathode electrode 4B and the anode electrode 12 is a reflective electrode, and the other is a transparent electrode.

Note that, in the present embodiment, the blue subpixel 2B includes the reflective cathode electrode 4B in a position overlapping the opaque region OA of the blue subpixel 2B, but is not limited thereto. For example, in the present embodiment, the blue subpixel 2B may include the cathode electrode 4B that is transparent and the anode electrode 12, which is a reflective electrode, in positions overlapping the opaque region OA of the blue subpixel 2B.

Further, in the present embodiment, the subpixel circuit 18B and the lead wiring line 20B are formed in positions overlapping the reflective cathode electrode 4BR. Therefore, in the present embodiment, a material having low transparency such as a metal material may be adopted for the lead wiring line 20B.

Note that the reflective cathode electrode 4BR and the transparent cathode electrode 4BT may be electrically connected to each other. According to this configuration, it is possible to drive the entire blue subpixel 2B by connecting the single subpixel circuit 18B with the reflective cathode electrode 4BR.

On the other hand, the reflective cathode electrode 4BR and the transparent cathode electrode 4BT may be electrically independent of each other. In this case, the display device 1 may include another subpixel circuit 18B that connects to the transparent cathode electrode 4BT separately from the subpixel circuit 18B that connects to the reflective cathode electrode 4BR, The subpixel circuit 18B connected to the transparent cathode electrode 4BT may be formed in a position overlapping the opaque region OA, and may be connected to the transparent cathode electrode 4BT via the lead wiring line 20B including a transparent material. According to the configuration described above, the opaque blue subpixel 2BO and the transparent blue subpixel 2BT can be individually driven, and an area gray scale can be performed in the blue subpixel 2B.

Except for the point described above, the display device 1 according to the present embodiment may have the same configuration as the display device 1 according to the first embodiment.

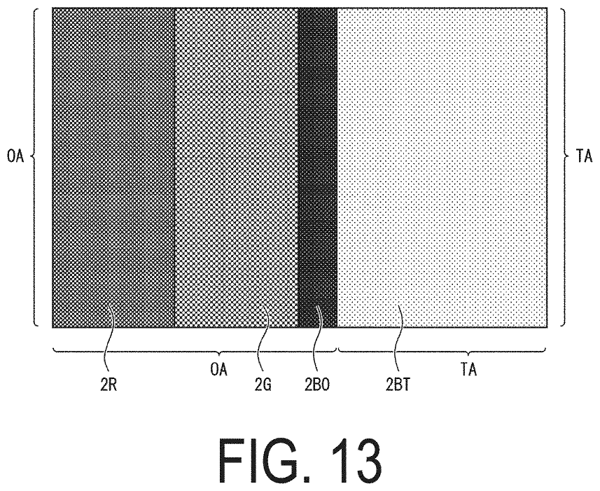

FIG. 13 is a schematic view illustrating the ratio of the area of each light-emitting subpixel to the total area of the red subpixel 2R, the green subpixel 2G, and the blue subpixel 2B in the present embodiment.

The ratio of the area of the transparent blue subpixel 2BT to the area of the blue subpixel 2B is denoted as c. Note that c is a real number greater than 0 and less than 1. Hereinafter, unless otherwise indicated, c is based on the definition described above.

In this case, the area of the entire blue subpixel 2B can be expressed as aS, the area of the transparent blue subpixel 2BT can be expressed as acS, and the area of the opaque blue subpixel 2BO can be expressed as a (1−c)S, Furthermore, in a case in which the areas of the red subpixel 2R and the green subpixel 2G are equal to each other, the areas of the red subpixel 2R and the green subpixel 2G can be respectively expressed as (S−aS)/2=(1−a)S/2.

Here, in the present embodiment, the transparent blue subpixel 2BT constitutes the transparent region TA, and the red subpixel 2R, the green subpixel 2G, and the opaque blue subpixel 2BO constitute the opaque region OA. Therefore, the area of the transparent region TA is acS, and the area of the opaque region OA is (1−ac)S.

Accordingly, the luminance of the blue subpixel 2B of the display device 1 according to the present embodiment is 3a(2−c) times the luminance of the blue subpixel 2B of the display device 1A according to the comparative embodiment. Further, the luminance of each of the red subpixel 2R and the green subpixel 2G of the display device 1 according to the present embodiment is 3(1−a) times the luminance of each of the red subpixel 2R and the green subpixel 2G of the display device 1A according to the comparative embodiment. Furthermore, the area of the transparent region TA of the display device 1 according to the present embodiment is 2ac times the area of the transparent region TA of the display device 1A according to the comparative embodiment.

In a case in which the luminance of each light-emitting subpixel of the display device 1 according to the present embodiment is to be made greater than or equal to the luminance of each light-emitting subpixel of the display device 1A according to the comparative embodiment, 3a(2−c)≥1 and 3(1−a)≥1 need only be satisfied. Accordingly, in a case in which c≤2−(1/(3a)) and a≤2/3, that is, the following relationship (7) is satisfied, the luminance of each light-emitting subpixel of the display device 1 according to the present embodiment can be made greater than or equal to the luminance of each light-emitting subpixel of the display device 1A according to the comparative embodiment.

$$\begin{matrix}[ Relationship 7 ] & \\ \frac{1}{3 ( 2 - c )} \leq a \leq \frac{2}{3} & ( 7 )\end{matrix}$$

Note that, in the calculation described above, the luminance at the position overlapping the opaque region OA of the light-emitting subpixel is ideally two-fold compared to that at the position overlapping the transparent region TA. Nevertheless, in reality, the luminance at a position overlapping the opaque region OA of the light-emitting subpixel is twice the luminance at the position overlapping the transparent region TA or less. This is because, as described above, the reflectivity R of light of the reflective electrode formed in a position overlapping the opaque region OA is less than 1, and the reflectivity R′ of light in the transparent electrode formed in a position overlapping the transparent region TA is greater than 0. When the actual reflectivity is considered, the relationship (7) described above is replaced with the following relationship (8).

$$\begin{matrix}[ Relationship 8 ] & \\ \frac{( 1 + R )}{6 \{ c ( {R}^{′} - R ) + ( 1 + R ) \}} \leq a \leq \frac{2}{3} & ( 8 )\end{matrix}$$

Furthermore, in a case in which the area of the transparent region TA of the display device 1 according to the present embodiment is to be made greater than or equal to the area of the transparent region TA of the display device 1A according to the comparative embodiment, the following relationship (9) need only be satisfied.

[Relationship9]

ac≥1/2 (9)

Accordingly, in a case in which the relationship (7) described above or the relationship (8) described above and the relationship (9) described above are satisfied, the area of the transparent region TA of the display device 1 according to the present embodiment can be made greater than or equal to the area of the transparent region TA of the display device 1A according to the comparative embodiment. Thus, according to the configuration described above, the luminance of the display device 1 can be secured and the area of the transparent region TA can be secured.

In the present embodiment, for example, a is 2/3, c is 9/10, and R=1 and R′=0. In this case, the area of the blue subpixel 2B is 2S/3, and the areas of the red subpixel 2R and the green subpixel 2G are each S/6. Further, the area of the transparent blue subpixel 2BT is 3S/5, and the area of the opaque blue subpixel 2BO is S/15. Furthermore, the area of the transparent region TA is 3S/5.

Accordingly, compared to the display device 1A according to the comparative embodiment, the display device 1 according to the present embodiment can achieve a 2.2-fold luminance of the blue subpixel 2B and a 1-fold luminance of each of the red subpixel 2R and the green subpixel 2G. Further, the display device 1 according to the present embodiment can secure a transparent region TA having a 1.2-fold area compared to that in the display device 1A according to the comparative embodiment.

The display device 1 according to the present embodiment is also preferable in that the luminance of the blue subpixel 2B can be made higher than the luminance of each of the red subpixel 2R and the green subpixel 2G, making it possible to compensate for low luminous efficiency.

In the present embodiment, the blue subpixel 2B includes an opaque blue subpixel 2BO included in the opaque region OA. Therefore, even in a case in which the subpixel circuit 18B or the lead wiring line 20B is formed in a position overlapping the opaque blue subpixel 2BO, the transmission of background light in the transparent blue subpixel 2BT is not affected.

Thus, in the display device 1 in the present embodiment, the subpixel circuit 18B or the lead wiring line 20B can be readily disposed at or near the blue subpixel 2B, and the subpixel circuit 18B or the lead wiring line 20B can be constituted by an opaque material.

### Fourth Embodiment

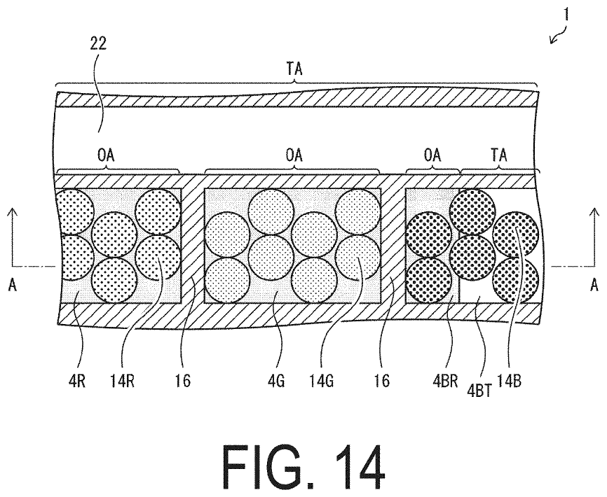

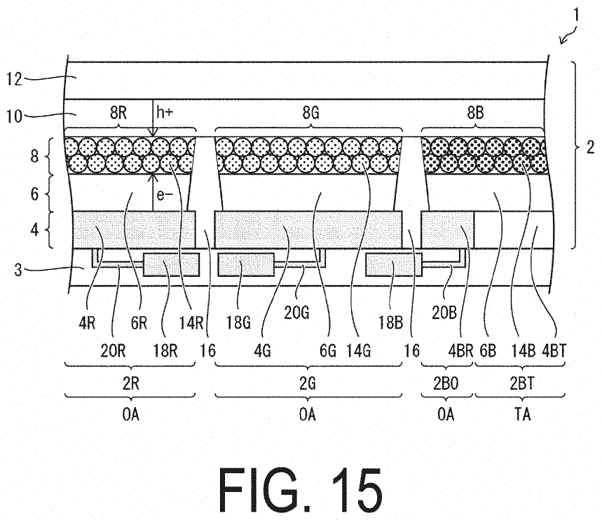

FIG. 14 is a top enlarged view of the display device 1 according to the present embodiment. FIG. 15 is a schematic cross-sectional view of the display device 1 according to the present embodiment, and is a cross-sectional view taken along line A-A in FIG. 14.

The display device 1 according to the present embodiment differs from the display device 1 according to the previous embodiment in further including the non-light-emitting transparent region 22 described in the second embodiment. That is, in the present embodiment, the opaque region OA includes the red subpixel 2R, the green subpixel 2G, and the opaque blue subpixel 2BO. Further, in the present embodiment, the transparent region TA includes the transparent blue subpixel 2BT and the non-light-emitting transparent region 22.

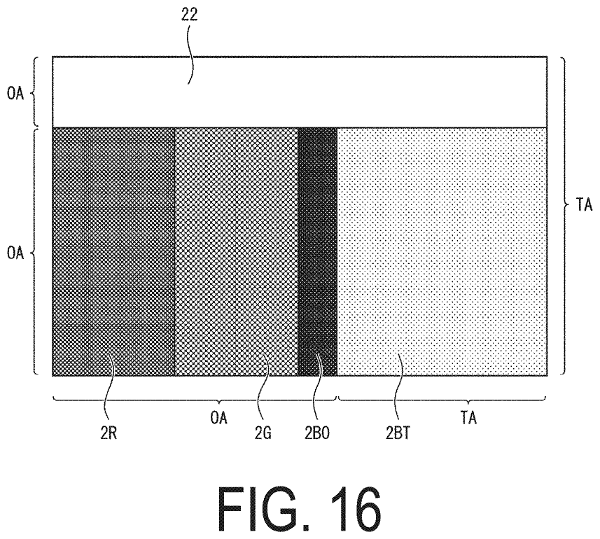

FIG. 16 is a schematic view illustrating the ratio of the area of each light-emitting subpixel and the ratio of the area of the non-light-emitting transparent region to the total area of the red subpixel 2R, the green subpixel 2G, the blue subpixel 2B, and the non-light-emitting transparent region 22 in the present embodiment.

In the present embodiment, the area of the non-light-emitting transparent region 22 can be expressed as bS, and the area of the blue subpixel 2B can be expressed as a(S−bS)=a(1−b)S. Further, the area of the transparent blue subpixel 2BT can be expressed as a(1−b)cS, and the area of the opaque blue subpixel 2BO can be expressed as a(1−b)·(1−c)S.

Furthermore, in a case in which the areas of the red subpixel 2R and the green subpixel 2G are equal to each other, the areas of the red subpixel 2R and the green subpixel 2G can be respectively expressed as ((1−b)S−a(1−b)S)/2=(1−a) (1−b)S/2.

Here, in the comparative embodiment, the transparent blue subpixel 2BT and the non-light-emitting transparent region 22 constitute the transparent region TA, and the red subpixel 2R, the green subpixel 2G, and the opaque blue subpixel 2BO constitute the opaque region OA. Therefore, the area of the transparent region TA is bS+a(1−b)cS=(ac(1−b) b)S, and the area of the opaque region OA is a(1−b)cS+(1−a)·(1−b)S (1−b)·(a(c−1)+1)S.

Accordingly, the luminance of the blue subpixel 2B of the display device 1 according to the present embodiment is 3a(1−b)·(2−c) times the luminance of the blue subpixel 2B of the display device 1A according to the comparative embodiment. Further, the luminance of each of the red subpixel 2R and the green subpixel 2G of the display device 1 according to the present embodiment is 3(1−a)·(1−b) times the luminance of each of the red subpixel 2R and the green subpixel 2G of the display device 1A according to the comparative embodiment. Furthermore, the area of the transparent region TA of the display device 1 according to the present embodiment is 2(ac(1−b)+b) times the area of the transparent region TA of the display device 1A according to the comparative embodiment.

In a case in which the luminance of each light-emitting subpixel of the display device 1 according to the present embodiment is greater than or equal to the luminance of each light-emitting subpixel of the display device 1A according to the comparative embodiment, the following relationship (10) and the following relationship (11) are satisfied.

[Relationship10]

3(1−a)(1−b)≥1 (10)

[Relationship11]

3a(1−b)(2−c)≥1 (11)

Note that, in the calculation described above, the luminance at the position overlapping the opaque region OA of the light-emitting subpixel is ideally two-fold compared to that at the position overlapping the transparent region TA. Nevertheless, in reality, the luminance at a position overlapping the opaque region OA of the light-emitting subpixel is twice the luminance at the position overlapping the transparent region TA or less. This is because, as described above, the reflectivity R of light of the reflective electrode formed in a position overlapping the opaque region OA is less than 1, and the reflectivity R′ of light in the transparent electrode formed in a position overlapping the transparent region TA is greater than 0. When the actual reflectivity is considered, the relationship (11) described above is replaced with the following relationship (12).

$$\begin{matrix}[ Relationship 12 ] & \\ \frac{6 a ( 1 - b ) \{ ( {R}^{′} - R ) c + 1 + R \}}{1 + R} \geq 1 & ( 12 )\end{matrix}$$

Furthermore, in a case in which the area of the transparent region TA of the display device 1 according to the present embodiment is to be made greater than or equal to the area of the transparent region TA of the display device 1A according to the comparative embodiment, the following relationship (13) need only be satisfied.

[Relationship13]

a(1−b)c+b≥½ (13)

Accordingly, in the present embodiment, it is desirable to satisfy the relationship (10) described above, the relationship (11) described above or the relationship (12) described above, and the relationship (13) described above. In a case in which the relationship (3) described above is satisfied, the area of the transparent region TA according to the present embodiment can be made greater than or equal to the area of the transparent region TA of the display device 1A according to the comparative embodiment while the luminance of each light-emitting subpixel of the display device 1 according to the present embodiment is improved.

In the present embodiment, for example, a is 2/5, b is 2/5, c is 3/5, and R and R′ are assumed to be 1 and 0, respectively. In this case, the area of the blue subpixel 2B is 6S/25, and the areas of the red subpixel 2R and the green subpixel 2G are each 9S/50. Further, the area of the transparent blue subpixel 2BT is 18S/125, and the area of the opaque blue subpixel 2BO is 12S/125. Furthermore, the area of the transparent region TA is 68S/125.

Accordingly, compared to the display device 1A according to the comparative embodiment, the display device 1 according to the present embodiment can achieve a 1.008-fold luminance of the blue subpixel 2B and a 1.08-fold luminance of each of the red subpixel 2R and the green subpixel 2G. Further, the display device 1 according to the present embodiment can secure a transparent region TA having a 1.088-fold area compared to that in the display device 1A according to the comparative embodiment.

### Fifth Embodiment

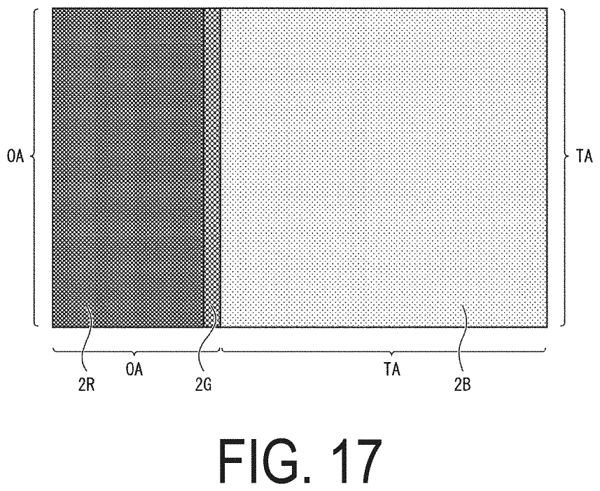

The display device 1 according to the present embodiment will now be described with reference to FIG. 17. The display device 1 according to the present embodiment may have the same configuration as that of the display device 1 according to the first embodiment except the ratio of the area of each light-emitting subpixel to the total area of the red subpixel 2R, the green subpixel 2G, and the blue subpixel 2B.

FIG. 17 is a schematic view illustrating the ratio of the area of each light-emitting subpixel to the total area of the red subpixel 2R, the green subpixel 2G, and the blue subpixel 2B in the present embodiment.

In the present embodiment, the ratio of the area of each light-emitting subpixel is determined in accordance with the luminous efficiency of each light-emitting subpixel and a luminosity factor for the human body with respect to the light from each light-emitting subpixel. Specifically, the product of the luminous efficiency and the luminosity factor is calculated and the ratio of the area of each light-emitting subpixel is determined based on the inverse of that product, for each light-emitting subpixel.

An example of the ratio of the area of each light-emitting subpixel in the present embodiment will now be described with reference to Table 1 below.

TABLE 1

| | QY | | | | | |
|---|---|---|---|---|---|---|
| | | RELATIVE | LUMINOSITY | | | AREA |
| SUBPIXEL | % | VALUE | FACTOR | PRODUCT | INVERSE | RATIO |
| RED | 90 | 1.1 | 0.1 | 0.1 | 8.9 | 0.29 |
| GREEN | 80 | 1.0 | 1.0 | 1.0 | 1.0 | 0.03 |
| BLUE | 32.5 | 0.4 | 0.1 | 0.05 | 20.5 | 0.67 |

In Table 1, the “Subpixel column” indicates which light-emitting subpixel among the red subpixel 2R, the green subpixel 2G, and the blue subpixel 2B corresponds to the numerical values. The “Red,” “Green,” and “Blue” rows indicate the numerical values for the red subpixel 2R, the green subpixel 2G, and the blue subpixel 2B, respectively.

In Table 1, the “QY” column indicates the quantum yield of each light-emitting subpixel. The “%” column indicates the quantum yield of each light-emitting subpixel as a percentage, and the “Relative Value” column indicates the relative value of the quantum yield of each light-emitting subpixel given 1.0 as the quantum yield of the green subpixel 2G. Note that, in the present embodiment, in consideration of the blue subpixel 2B being formed in the transparent region TA, the quantum yield of blue in Table 1 is a value equivalent to half of the quantum yield of the actual material itself.

The “Luminosity Factor” column indicates the luminosity factor for the human body with respect to the light from each light-emitting subpixel. Note that the luminosity factor with respect to the light emitted from the green subpixel 2G, that is, the green light, is set to 1.0. Accordingly, the luminosity factors with respect to the red light from the red subpixel 2R and the blue light from the blue subpixel 2B indicate relative values when compared to the luminosity factor to the green light.

The “Product” column is the numerical value obtained by multiplying the value of “Relative Value” of “QY” described above by the value of “Luminosity Factor” for each light-emitting subpixel. The “Inverse” is the inverse of the product for each light-emitting subpixel. The “Area. Ratio” is the area ratio of each light-emitting subpixel found from the value of “Inverse”. Specifically, the area ratio of each light-emitting subpixel is a value obtained by compressing the value of “Inverse” of each light-emitting subpixel so that the total value is 1.

Note that, because the numerical values in Table 1 are partially rounded up or rounded down, the exact numerical values may differ.

As shown in Table 1, in the present embodiment, it is determined that the area of the red subpixel 2R is approximately 29% of the overall area, the area of the green subpixel 2G is approximately 3% of the overall area, and the area of the blue subpixel 2B is approximately 67% of the overall area. Therefore, in comparison to the display device 1 according to each embodiment described above, in the display device 1 according to the present embodiment, the areas of the red subpixel 2R and the green subpixel 2G differ from each other.

In the present embodiment as well, the blue subpixel 2B transmits background light, and the red subpixel 2R and the green subpixel 2G block background light. Therefore, unexpected light emission by the red subpixel 2R and the green subpixel 2G due to background light can be suppressed.

In addition, in the present embodiment, the configuration is such that the smaller the product of the luminous efficiency and luminosity factor of each light-emitting subpixel, the larger the ratio of the area of each light-emitting subpixel. Therefore, the luminance of the red subpixel 2R, the green subpixel 2G, and the blue subpixel 2B emitted at the same current value are equal. Accordingly, the display device 1 according to the present embodiment does not only improve the white balance, but can simplify the drive circuit and a color reproduction algorithm.

Further, in general, the luminous efficiency of the blue subpixel 2B is low, and the luminosity factor for the human body with respect to blue light is low. Therefore, in the present embodiment, the area of the blue subpixel 2B needs to be larger than the area of the red subpixel 2R and the green subpixel 2G. Accordingly, the display device 1 according to the present embodiment can secure the transmission region TA more efficiently while improving the luminance of each light-emitting subpixel.

In particular, in the example described above, the area of the blue subpixel 2B occupies approximately 67% of the overall area. Therefore, in the present embodiment, the luminance of the blue subpixel 2B can be approximately 4-fold compared to that in the display device 1A according to the comparative embodiment. Further, the display, device 1 according to the present embodiment can secure a transparent region TA having an approximate 4/3-fold area compared to that in the display device 1A according to the comparative embodiment.

In the present embodiment, quantum yield is used as the luminous efficiency of each light-emitting subpixel in the calculation of the area ratio of each light-emitting subpixel, but is not limited thereto. For example, in the present embodiment, the ratio of the area of each light-emitting subpixel may be determined from the inverse of the product of an external quantum efficiency of each light-emitting subpixel and the luminosity factor for the human body with respect to the light of each light-emitting subpixel.

The disclosure is not limited to the embodiments described above, and various modifications may be made within the scope of the claims. Embodiments obtained by appropriately combining technical approaches disclosed in the different embodiments also fall within the technical scope of the disclosure. Furthermore, novel technical features can be formed by combining the technical approaches disclosed in each of the embodiments.

### REFERENCE SIGNS LIST

1 Display device
2 Light-emitting element
2R Red subpixel.
2G Green subpixel
2B Blue subpixel
2BT Transparent blue subpixel
2BO Opaque blue subpixel
3 Array substrate
4 Cathode electrode
6 Electron transport layer
8 Light-emitting layer
8R Red light-emitting layer
8G Green light-emitting layer
8B Blue light-emitting layer
10 Hole transport layer
12 Anode electrode
14R Red quantum dot (first quantum dot)
14G Green quantum dot (second quantum dot)
14B Blue quantum dot
22 Non-light-emitting transparent region
OA Opaque region
TA Transparent region

1. A light-emitting device of a transmissive type provided with, as subpixels, a red subpixel including a red light-emitting layer, a green subpixel including a green light-emitting layer, and a blue subpixel including a blue light-emitting layer arranged in parallel with one another, the light-emitting device comprising:
an opaque region that overlaps at least the red subpixel and the green subpixel, each in its entirety, in a plan view and blocks background light; and
a transparent region that overlaps at least a portion of the blue subpixel in a plan view and transmits background light.

2. The light-emitting device according to claim 1,
wherein the red light-emitting layer includes a first quantum dot that emits red light, and
the green light-emitting layer includes a second quantum dot that emits green light.

3. The light-emitting device according to claim 1,
wherein the red subpixel, the green subpixel, and the blue subpixel each include an anode electrode and a cathode electrode,
in each of the red subpixel and the green subpixel, one of the anode electrode and the cathode electrode is a reflective electrode and the other is a transparent electrode, and
in the blue subpixel, both the anode electrode and the cathode electrode include a transparent electrode in a position overlapping the transparent region.

4. The light-emitting device according to claim 3,
wherein a portion of the blue subpixel overlaps the opaque region, and one of the anode electrode and the cathode electrode in the opaque region is a reflective electrode and the other is a transparent electrode.

5. The light-emitting device according to claim 1,
wherein, the transparent region overlaps the blue subpixel in its entirety in a plan view.

6. The light-emitting device according to claim 5,
wherein given a is a ratio of an area of the blue subpixel to a total area of the red subpixel, the green subpixel, and the blue subpixel in a plan view, the following relationship (1) is satisfied.
[Relationship1]
⅓≤a≤2/3 (1)

7. The light-emitting device according to claim 3,
wherein the transparent region overlaps the blue subpixel in its entirety in a plan view, and
given a is a ratio of an area of the blue subpixel to a total area of the red subpixel, the green subpixel, and the blue subpixel in a plan view, R is a reflectivity of light of the reflective electrode, and R′ is a reflectivity of light of the transparent electrode, the following relationship (2) is satisfied.
$$\begin{matrix}[ Relationship 2 ] & \\ \frac{1 + R}{6 ( 1 + {R}^{′} )} \leq a \leq \frac{2}{3} & ( 2 )\end{matrix}$$

8. The light-emitting device according to claim 6,
wherein the following relationship (3) is further satisfied.
[Relationship3]
a≥½ (3)

9. The light-emitting device according to claim 1,
wherein the transparent region includes a non-light-emitting transparent region surrounding the subpixels in a plan view.

10. The light-emitting device according to claim 9,
wherein given a is a ratio of an area of the blue subpixel to a total area of the red subpixel, the green subpixel, and the blue subpixel, and b is a ratio of an area of the non-light-emitting transparent region to a total area of all of the transparent regions and the opaque regions in a plan view, the following relationship (4) is satisfied.
$$\begin{matrix}[ Relationship 4 ] & \\ \frac{1}{3 ( 1 - b )} \leq a \leq \frac{2 - 3 b}{3 ( 1 - b )} & ( 4 )\end{matrix}$$

11. The light-emitting device according to claim 3,
wherein the transparent region includes a non-light-emitting transparent region surrounding the subpixels in a plan view, and
given a is a ratio of an area of the blue subpixel to a total area of the red subpixel, the green subpixel, and the blue subpixel, and b is a ratio of an area of the non-light-emitting transparent region to a total area of all of the transparent regions and the opaque regions in a plan view, R is a reflectivity of light of the reflective electrode, and R′ is a reflectivity of light of the transparent electrode, the following relationship (5) is satisfied.
$$\begin{matrix}[ Relationship 5 ] & \\ \frac{1 + R}{6 ( 1 + {R}^{′} ) ( 1 - b )} \leq a \leq \frac{2 - 3 b}{3 ( 1 - b )} & ( 5 )\end{matrix}$$

12. The light-emitting device according to claim 10,
wherein the following relationship (6) is further satisfied.
$$\begin{matrix}[ Relationship 6 ] & \\ \frac{1 - 2 b}{2 ( 1 - b )} \leq a & ( 6 )\end{matrix}$$

13. The light-emitting device according to claim 1,
wherein the opaque region overlaps a portion of the blue subpixel in a plan view.

14. The light-emitting device according to claim 13,
wherein given a is a ratio of an area of the blue subpixel to a total area of the red subpixel, the green subpixel, and the blue subpixel, and c is a ratio of an area of the transparent region overlapping the blue subpixel to the total area of the red subpixel, the green subpixel, and the blue subpixel in a plan view, the following relationship (7) is satisfied.
[Relationship7]
1/3(2−c)≤a≤⅔ (7).

15. The light-emitting device according to claim 3,
wherein the opaque region overlaps a portion of the blue subpixel in a plan view, and
given a is a ratio of an area of the blue subpixel to a total area of the red subpixel, the green subpixel, and the blue subpixel, and c is a ratio of an area of the transparent region overlapping the blue subpixel to the total area of the red subpixel, the green subpixel, and the blue subpixel in a plan view; R is a reflectivity of light of the reflective electrode, and R′ is a reflectivity of light of the transparent electrode, the following relationship (8) is satisfied.
$$\begin{matrix}[ Relationship 8 ] & \\ \frac{( 1 + R )}{6 \{ c ( {R}^{′} - R ) + ( 1 + R ) \}} \leq a \leq \frac{2}{3} & ( 8 )\end{matrix}$$

16. The light-emitting device according to a 14 or 15,
wherein the following relationship (9) is further satisfied.
[Relationship9]
ac≥½ (9)

17. The light-emitting device according to claim 13,
wherein the transparent region includes a non-light-emitting transparent region surrounding the subpixels in a plan view.

18. The light-emitting device according to claim 17,
wherein given a is a ratio of an area of the blue subpixel to a total area of the red subpixel, the green subpixel, and the blue subpixel, and b is a ratio of an area of the non-light-emitting transparent region to a total area of all of the transparent regions and the opaque regions, and c is a ratio of an area of the transparent region overlapping the blue subpixel to the total area of the red subpixel, the green subpixel, and the blue subpixel in a plan view, the following relationship (10) and the following relationship (11) are satisfied.
[Relationship10]
3(1−a)(1−b)≥1 (10)
[Relationship11]
3a(1−b)(2−c) (11)

19. The light-emitting device according to claim 3,
wherein the opaque region overlaps a portion of the blue subpixel in a plan view,
the transparent region includes a non-light-emitting transparent region surrounding the subpixel in a plan view, and
given a is a ratio of an area of the blue subpixel to a total area of the red subpixel, the green subpixel, and the blue subpixel, b is a ratio of an area of the non-light-emitting transparent region to a total area of all of the transparent regions and the opaque regions, and c is a ratio of an area of the transparent region overlapping the blue subpixel to the total area of the red subpixel, the green subpixel, and the blue subpixel in a plan view, R is a reflectivity of light of the reflective electrode, and R′ is a reflectivity of light of the transparent electrode, the following relationship (10) and the following relationship (12) are satisfied.
$$\begin{matrix}[ Relationship 10 ] & \\ 3 ( 1 - a ) ( 1 - b ) \geq 1 & ( 10 )\end{matrix}$$
$$\begin{matrix}[ Relationship 12 ] & \\ \frac{6 a ( 1 - b ) \{ ( {R}^{′} - R ) c + 1 + R \}}{1 + R} \geq 1 & ( 12 )\end{matrix}$$

20. The Light-emitting device according to claim 18,
wherein the following relationship (13) is further satisfied.
[Relationship13]
a(1−b)c+b≥½ (13)

21-23. (canceled)
